(19) United States
(12) Patent Application Publication
(10) Pub. No.: US 2026/0246474 A1
(43) Pub. Date: Aug. 20, 2026

(54) Multiple PLL System with Pairwise Phase Difference Regulation

(71) Applicant: Telefonaktiebolaget LM Ericsson (publ), Stockholm (SE)

(72) Inventors: Staffan Ek, Lund (SE); Henrik Sjöland, Lund (SE)

(21) Appl. No.: 18/869,694

(22) PCT Filed: Jun. 2, 2022
(86) PCT No.: PCT/EP2022/065085

§ 371 Date: Nov. 26, 2024

(51) Int. Cl. H03L 7/23; H03L 7/099; H03L 7/197

(52) U.S. Cl. CPC H03L 7/23; H03L 7/087; H03L 7/093; H03L 7/22

(57) ABSTRACT

A system of pairwise phase noise difference regulation for Phase Locked Loops (PLL) is disclosed. A phase difference detector receives a periodic signal from each of two PLLs, and compares their phases. One or more error signals indicating a deviation from a targeted phase difference between the periodic signals, and also indicating which signal leads the other in phase, are feed back to the two PLLs. At least one of the PLLs adjusts it controlled oscillator so as to minimize or eliminate the error signal, locking the two PLLs together (or at a targeted offset) in phase. Each PLL may also be pairwise phase locked to one or more different PLLs, via a different phase difference detector. In this manner, each PLL operates with at least two feedback loops. A conventional reference tracking loop operates with low bandwidth and high DC gain to ensure that the phase and frequency of the PLL output tracks a reference periodic signal, but that correlated noise from the reference is not contributing more phase noise than necessary. One or more pairwise phase difference regulation loops operate at a higher bandwidth to lock the phase (or phase offset) between the oscillators of pairwise associated PLLs, ensuring minimum phase noise, as the uncorrelated noise of the PLLs is suppressed already before signal combination. Potential oscillator interaction is well suppressed by the wide bandwidth of the pairwise phase difference regulation loops. The PLLs may output different frequency signals, on a frequency grid having a spacing of the reference frequency, while still minimizing phase deviations.

### TECHNICAL FIELD

The present disclosure relates generally to periodic signal generation in Phase Locked Loops (PLL), and in particular to a system and method of pairwise phase difference regulation of PLLs that mitigates phase noise and the effects of oscillator coupling.

### BACKGROUND

Wireless communication networks, including network nodes and radio network devices such as cellphones and smartphones, are ubiquitous in many parts of the world. These networks continue to grow in capacity and sophistication. To accommodate both more users and a wider range of types of devices that may benefit from wireless communications, the technical standards governing the operation of wireless communication networks continue to evolve. The fourth generation of network standards (4G, also known as Long Term Evolution, or LTE) has been deployed, the fifth generation (5G, also known as New Radio, or NR) is in development or the early stages of deployment, and the sixth generation (6G) is being planned.

One important development in modern wireless communication networks is the use of spatial diversity and/or spatial multiplexing. Spatial diversity refers to transmitting the same signal on different propagation paths (e.g., different transmit/receive antennas), which increases robustness against fading, co-channel interference, and other deleterious effects of RF signal transmission. Spatial multiplexing also uses multiple transmit and receive antennas, and refers to transmitting different portions of data on different propagation paths, using space-time coding, to increase data rates. These techniques are collectively referred to as Multiple Input, Multiple Output, or “MIMO.” The key to all MIMO techniques is the deployment of multiple antennas, on at least one and preferably both sides of the air interface channel. 4G network standards contemplate 2, 4, or 8 antennas per transceiver; 5G networks envision up to 128 antennas per transceiver; and the number could go far higher in 6G networks. In highly parallel architectures, each antenna used to transmit or receive an RF signal is associated with a dedicated transceiver. Each transceiver requires either a Local Oscillator (LO) signal to perform frequency conversion between carrier frequencies (for transmission/reception) and baseband (for signal processing), or an RF-speed Analog to Digital Converter (ADC) for direct RF sampling. For efficient, low power processing of received signals, and for the transmission of coherent signals from multiple antennas, phase coherence of the multiple LO signals is important.

Another advanced feature of modern wireless communication networks is beamforming, wherein the directionality of an RF transmission is increased and controlled to “aim” in a specific direction. This may be accomplished by the use of a phased-array antenna comprising a large plurality of antenna elements. The relative phases of transmit signals sent to each antenna element are controlled to create constructive or destructive interference, thus amplifying the signal in some directions and attenuating it in others, and hence controlling the direction in which the beam is transmitted. Similar phase manipulation of signals from antenna elements in a receive antenna can also result in beamforming the sensitivity of a phased-array antenna in receiving signals. In such beamforming systems, the LO signals at each antenna element transceiver must be phase-aligned, to allow for precise control of the phase offsets.

Typically, an LO signal is generated using a phase locked loop (PLL). A PLL is a well-known circuit, in which a Controlled Oscillator (i.e., an analog Voltage Controlled Oscillator, VCO, or a Digitally Controlled Oscillator, DCO) generates a high-frequency periodic signal, such as an LO signal. The generated periodic signal is at a frequency that is a predetermined multiple of a reference signal, such as a clock signal from a crystal oscillator or other accurate source. In a reference feedback loop within the PLL, a Phase-Frequency Detector compares a frequency-divided version of the VCO/DCO output signal with the reference signal, to generate error signals indicative of frequency or phase deviation. The error signals are processed by a loop filter, which provides an input to the VCO/DCO that keeps the output signal frequency- and phase-locked to the reference signal. The output frequency of the PLL may be changed by changing frequency of the reference signal input, or by adjusting the divisor in the frequency division circuit.

As indicated above, a PLL may operate in the analog or digital domain. Advantages of a digital PLL include the absence of large area capacitors in the analog loop filter, and the possibility to support advanced digital algorithms, such as to implement high-speed frequency hops. On the other hand, advantages of an analog PLL include reduced design complexity and excellent phase noise. As one example of the design trade-offs, the simplicity of an analog PLL makes it an excellent choice at very high frequencies or very low power. However, this choice sacrifices the possibility for digital algorithms to achieve improved performance. Regardless of the PLL architecture selected, however, a key concern is achieving sufficiently low phase noise, with limited power consumption and chip area, without sacrificing performance in other aspects.

Whether an analog or digital PLL architecture is selected, there are different options for distributing an LO signal to a large number of transceivers across an Integrated Circuit (IC). One option is to employ a single, very high performance PLL, and distribute one LO signal over the IC to each transceiver. Another option is to provide a separate PLL at each transceiver. Numerous intermediate options are possible, in which two or more PLLs, distributed over the IC, each provide an LO signal to some number of nearby transceivers. Each design option has advantages and disadvantages.

A single PLL offers the advantages of providing correlated phase noise to all transceivers, and no deleterious effects from the interaction of multiple PLLs operating at the same frequency. However, the noise performance requirement of a single PLL then becomes stringent, and routing a high-frequency LO signal presents numerous known challenges (e.g., high power consumption, and maintaining phase match and low phase-noise through multiple buffers).

There are several advantages to the use of multiple PLLs (whether one per transceiver or one per multiple transceivers). Their phase noises are non-correlated, other than noise originating from the common reference signal. Hence, the phase noise requirement of each PLL can be relaxed, and sufficient system performance can still be achieved when the signals are combined by their use in different transceivers. Although the total power consumption of multiple PLLs may be on par with that of a single PLL, considerable power consumption reduction can be realized by eliminating the LO signal distribution network. Furthermore, elimination of the LO distribution network makes the entire design more modular, allowing for the addition or removal of PLLs and corresponding transceivers with minimal design effort. On the other hand, the use of multiple PLLs raises a risk of undesired interaction between them, particularly in cases where the IC is so compact that distances between the inductors of the oscillators are limited.

The Background section of this document is provided to place aspects of the present disclosure in technological and operational context, to assist those of skill in the art in understanding their scope and utility. Approaches described in the Background section could be pursued, but are not necessarily approaches that have been previously conceived or pursued. Unless explicitly identified as such, no statement herein is admitted to be prior art merely by its inclusion in the Background section.

### SUMMARY

The following presents a simplified summary of the disclosure in order to provide a basic understanding to those of skill in the art. This summary is not an extensive overview of the disclosure and is not intended to identify key/critical elements of embodiments of the invention or to delineate the scope of the invention. The sole purpose of this summary is to present some concepts disclosed herein in a simplified form as a prelude to the more detailed description that is presented later.

Aspects of the present disclosure described and claimed herein provide a system of pairwise phase difference regulation. A phase difference detector receives a periodic signal from each of two PLLs, and compares the phases of these signals. The phase difference detector outputs, to both of the PLLs, error signals indicating a phase difference between the periodic signals, and also indicating which signal leads the other in phase. At least one of the PLLs adjusts its controlled oscillator so as to minimize or eliminate the error signal, locking the two PLLs together in phase. Each PLL may also be pairwise phase locked to one or more different PLL, via a different phase difference detector. In this manner, each PLL operates with at least two feedback loops.

A conventional reference tracking loop operates at low bandwidth and with an integrator in the loop filter. The bandwidth of the reference tracking loop is set to about the offset frequency where the phase noise of the upconverted reference equals the phase noise of all high frequency oscillators operating jointly as a single unit. The reference tracking loop keeps the frequency and phase of each PLL of the system locked to the reference.

Additionally, each PLL has one or more pairwise phase difference feedback loops, based on the difference between its phase and the phase of the other PLL in the pair. The bandwidth of the pairwise difference feedback loop is to be chosen as high as possible, limited by the phase margin that can be achieved with the comparison frequency used (which may be chosen relatively freely compared to the reference frequency). The pairwise difference feedback loop operates to keep the oscillators of associated PLLs in a desired phase relationship with each other (i.e., either in phase, or with a desired phase offset). As the reference tracking loops contain integrators, they will make sure that the average phase relation between reference and output is as intended, and the pairwise difference feedback loops allow for a certain degree of DC phase difference, and are still able to correct for rapid phase changes. The wide bandwidth reduces effects of coupling between PLLs over a wide frequency range.

The use of two separate feedback loops maximizes performance. The low bandwidth, high DC gain reference tracking loops ensure that the phase and frequency of the PLL outputs track the reference, but that correlated noise from the reference periodic signal is not contributing more phase noise than necessary. The wideband pairwise difference feedback loops lock the phase between the oscillators of associated PLLs, ensuring minimum phase noise, as the uncorrelated noise of the PLLs is suppressed already before signal combination. Potential oscillator interaction is well suppressed by the wide bandwidth of the pairwise phase difference regulation loops.

In some aspects, a plurality of different frequency PLL output signals (e.g., LO signals) are generated, enabling the reception and transmission of different carriers. However, the LO signal frequencies are on a frequency grid, having a granularity of the reference frequency. That is, all PLL circuits generate signals at integer multiples of the reference frequency. In one aspect, the PLL circuits all operate with integer-N dividers. In these aspects, the PLL circuits phase-lock together (optionally with phase offsets) in pairwise fashion, using signals at the reference frequency. It is then possible to compare the phase deviations between pairs of PLL circuits, even though they generate LO signals at different frequencies, as the reference signals are at the same frequency. Accordingly, the phases of the different pairs of LO signals, when frequency divided to (or sampled at) the reference frequency, will have a constant relation when the PLL circuits are phase-locked and stable at various integer multiples of the reference frequency. Phase drift between pairs of PLL circuits is then detected and corrected, notwithstanding that the PLL circuits are operating to generate different frequency LO signals.

In another aspect where output frequencies differ, PLL circuits have different fractional relationships to the reference frequency, but the relationship between their output frequencies is an integer number. In some aspects, PLL circuits have two frequency dividers-one for the reference tracking loop, and one for the pairwise difference feedback loop. This allows for fractional division in the reference tracking loop, using a modulated division number (e.g., employing ΔΣ modulation). In this case, the frequency of the signals used for the pairwise difference feedback loop will deviate slightly from the reference frequency. In another aspect, The PLLs have only one modulated divider, and the modulator controlling the division ratio is common to both (or more) PLLs in pairwise locking relationship.

One aspect of the present disclosure relates to a pairwise phase difference regulation system. The system includes first and second Phase Locked Loops (PLL), each comprising a controlled oscillator configured to generate an output periodic signal that is phase-locked to a reference periodic signal (Ref), in response to a reference tracking feedback loop. The system further includes a first phase difference detector configured to receive a first periodic signal from the first PLL and a second periodic signal from the second PLL, and output one or more error signals representing a deviation from a targeted phase difference between the first and second periodic signals, and identifying which of the first and second periodic signals leads in phase. Each of the first and second PLLs is configured to control its oscillator in response to both the one or more error signals representing a phase difference between the first and second periodic signals, and its reference tracking feedback loop. The first phase difference detector and first and second PLLs form a pairwise phase difference feedback loop operative to minimize a deviation from a targeted phase difference between the output periodic signals of the first and second PLLs.

Another aspect relates to a method of generating a plurality of periodic signals. A plurality of PLLs is provided. Each PLL comprises a controlled oscillator configured to generate an output periodic signal that is phase-locked to a reference periodic signal, in response to a reference tracking feedback loop. A first periodic signal from a first PLL is compared to a second periodic signal from a second PLL, to generate one or more error signals representing a phase difference between the first and second periodic signals, and identifying which of the first and second periodic signals leads in phase. The oscillator in each of the first and second PLLs is controlled in response to both the one or more error signals representing a deviation from a targeted phase difference between the first and second periodic signals, and its reference tracking feedback loop, so as to minimize a phase difference between the output periodic signals of the first and second PLLs.

Yet another aspect relates to User Equipment (UE) operative in a wireless communication network, the UE including one or more transceiver circuits. Each transceiver circuit includes a plurality of Phase Locked Loops (PLL). Each PLL comprises a controlled oscillator configured to generate an output periodic signal that is phase-locked to a reference periodic signal (Ref), in response to a reference tracking feedback loop. The system further includes a first phase difference detector configured to receive a first periodic signal from the first PLL and a second periodic signal from the second PLL, and output one or more error signals representing a deviation from a targeted phase difference between the first and second periodic signals, and identifying which of the first and second periodic signals leads in phase. Each of the first and second PLLs is configured to control its oscillator in response to both the one or more error signals representing a phase difference between the first and second periodic signals, and its reference tracking feedback loop. The first phase difference detector and first and second PLLs form a pairwise phase difference feedback loop operative to minimize a deviation from a targeted phase difference between the output periodic signals of the first and second PLLs.

Still another aspect relates to a base station operative in a wireless communication network, the base station including one or more transceiver circuits. Each transceiver circuit includes a plurality of Phase Locked Loops (PLL). Each PLL comprises a controlled oscillator configured to generate an output periodic signal that is phase-locked to a reference periodic signal (Ref), in response to a reference tracking feedback loop. The system further includes a first phase difference detector configured to receive a first periodic signal from the first PLL and a second periodic signal from the second PLL, and output one or more error signals representing a deviation from a targeted phase difference between the first and second periodic signals, and identifying which of the first and second periodic signals leads in phase. Each of the first and second PLLs is configured to control its oscillator in response to both the one or more error signals representing a phase difference between the first and second periodic signals, and its reference tracking feedback loop. The first phase difference detector and first and second PLLs form a pairwise phase difference feedback loop operative to minimize a deviation from a targeted phase difference between the output periodic signals of the first and second PLLs.

### BRIEF DESCRIPTION OF THE DRAWINGS

The present disclosure will now be described more fully hereinafter with reference to the accompanying drawings, in which aspects of the disclosure are shown. However, this disclosure should not be construed as limited to the aspects set forth herein. Rather, these aspects are provided so that this disclosure will be thorough and complete, and will fully convey the scope of the invention to those skilled in the art. Like numbers refer to similar elements throughout.

FIG. 1 is a schematic diagram of a Phase Locked Loop (PLL) system having pairwise phase difference regulation, according to one aspect of the present disclosure.

FIG. 2 is a schematic diagram of a Phase Difference Detector (PD Diff).

FIG. 3 is a schematic diagram of a PLL system having pairwise phase difference regulation, according to another aspect.

FIG. 4 is a schematic diagram of a PLL system having pairwise phase difference regulation, according to yet another aspect.

FIG. 5 is a schematic diagram of a Controlled Oscillator having multiple control inputs.

FIG. 6 is frequency domain graph showing an example of PLL circuit output frequencies, corresponding LO frequencies, and carrier signals.

FIG. 7 is a schematic diagram of a PLL system having pairwise phase difference regulation, wherein PLLs have multiple frequency dividers.

FIG. 8 is a schematic diagram of a PLL system having pairwise phase difference regulation, wherein PLLs have fractional dividers with a common modulator.

FIG. 9 is plot of phase noise vs. log offset frequency for PLLs with and without pairwise phase difference regulation.

FIG. 10 is plot of phase noise vs. log frequency for 3-PLL systems with and without pairwise phase difference regulation.

FIG. 11 depicts graphs of PLL control voltage responses of 3-PLL systems with (upper) and without (lower) pairwise phase difference regulation, as a 100 degree phase shift is applied.

FIG. 12 depicts graphs of PLL control voltage responses of 3-PLL systems with (upper) and without (lower) pairwise phase difference regulation, as 45 degree phase steps are applied between 0 and 180 degrees.

FIG. 13 is hardware block diagram of a PLL system having pairwise phase difference regulation in a ring topology.

FIG. 14 is block diagram of a PLL system having pairwise phase difference regulation in a grid topology.

FIG. 15 is a flow diagram of steps of a method of generating a plurality of periodic signals.

FIG. 16A is a diagram of transmission on the air interface of a wireless communication network.

FIG. 16B is a hardware block diagram of the UE of FIG. 12A.

FIG. 16C is a hardware block diagram of the base station of FIG. 12A.

### DETAILED DESCRIPTION

For simplicity and illustrative purposes, the present disclosure is described by referring mainly to an exemplary aspect thereof. In the following description, numerous specific details are set forth in order to provide a thorough understanding of the present disclosure. However, it will be readily apparent to one of ordinary skill in the art that the present disclosure may be practiced without limitation to these specific details. In this description, well known methods and structures have not been described in detail so as not to unnecessarily obscure the present disclosure.

Aspects of the present disclosure provide a system of distributed Local Oscillator (LO) or Clock (CLK) signal generation with local PLLs, and a lower frequency reference periodic signal. This approach is attractive for power consumption, and the localized high frequency facilitates modularity of design. Using pairwise phase difference regulation, the PLLs are locked to each other with high bandwidth, thus reducing phase noise and effects of potential undesired oscillator coupling, but without sacrificing design modularity. The bandwidth of the PLLs' reference tracking loops is set independently of the pairwise phase difference feedback loop, optimizing phase noise performance without sacrificing suppression of oscillator coupling effects achieved by the pairwise phase difference regulation.

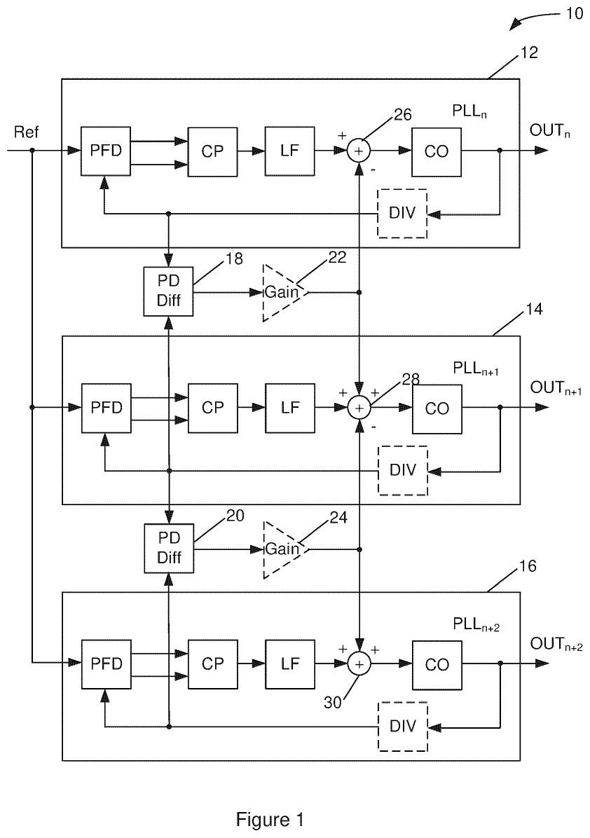

FIG. 1 depicts a system 10 comprising a plurality of Phase Locked Loops (PLL) PLLₙ 12, PLLₙ₊₁ 14, and PLLₙ₊₂ 16 having pairwise phase difference regulation. These PLLs may comprise any type of PLL, such as analog, digital, or a hybrid. As one example of the latter, pending PCT application PCT/2020/078369, titled “Digitally Augmented PLL for Accurate Transfer Function,” filed 19 Oct. 2020, assigned to the assignee of the present disclosure, and incorporated herein by reference in its entirety, describes a hybrid analog/digital PLL that advantageously uses a digital control word for rapid frequency changes, such as in frequency-hopping RF communications transceivers. Accordingly, any or all of the PLLs in FIG. 1 may include additional circuitry, the operation of which is not germane to the present disclosure.

The basic PLL is well known in the art. A controlled oscillator CO generates a periodic output signal OUTₙ, OUTₙ₊₁, OUTₙ₊₂, that is phase-locked to a reference periodic signal Ref, in response to an oscillator control signal generated by a reference tracking feedback loop. The reference tracking feedback loop includes an optional divider DIV, which divides the frequency of the output signal OUT by a fixed or programmable value (a PLL without a DIV may be considered to divide its output frequency by 1). The divided output signal is compared to the reference periodic signal Ref in a phase and frequency detector PFD. The PFD typically outputs a sequence of either UP or DOWN pulses in response to a detected frequency or phase difference between the PFD inputs. In response to the UP or DOWN pulses, a charge pump CP injects positive or negative charge into, e.g., a capacitor in a loop filter LF, which outputs a voltage signal, which is typically an input to the controlled oscillator CO. The DIV, PFD, CP, and LF form a reference tracking feedback loop that locks the divided output signal to the phase of the reference periodic signal Ref, at a frequency that is equal to or greater than the reference periodic signal Ref, depending on the value of DIV.

As depicted in FIG. 1, a phase difference detector PD Diff is connected between two PLLs. For example, a first PD Diff 18 is connected between PLL 12 and PLL 14, and a second PD Diff 20 is connected between PLL 14 and PLL 16. Operation of the PD Diffs 18, 20 will be discussed with reference to the first PD Diff 18 and its associated PLLs 12, 14. FIG. 1 depicts the PD Diff 18 comparing the divided output signals of PLLs 12, 14, which may be advantageous as it reduces the frequency of signals routed between the PLLs 12, 14 and PD Diff 18. However, in some aspects the PD Diff 18 compares the phases of the output periodic signals OUTₙ and OUTₙ₊₁. As used herein, the term “periodic signal” encompasses both cases—e.g., a first periodic signal from a first PLL 12 and a second periodic signal from a second PLL 14 may both be either the PLL output or a divided version of the PLL output.

The PD Diff 18 outputs an error signal indicating a detected phase difference between its two periodic input signals, and identifying which of the associated PLLs 12, 14 leads in phase. The error signal is optionally amplified by a gain circuit 22, and then combined with the output of the reference tracking feedback loop in each PLL 12, 14. In one embodiment, the PD Diff 18 outputs a positive error signal if the PLL 12 leads in phase, and a negative error signal if the PLL 14 leads in phase. In this embodiment, the error signal is subtracted from the reference tracking feedback loop output of PLL 12 at adder 26, and added to the reference tracking feedback loop output of PLL 14 at adder 28. The outputs of the adders 26, 28 then control the respective COs in PLL 12, 14, respectively. Accordingly, if the PLL 12 leads in phase, a positive error signal is subtracted from the reference tracking feedback loop output of PLL 12, reducing the input to the CO of PLL 12 and retarding its phase. Simultaneously, the positive error signal is added to the reference tracking feedback loop output of PLL 14, increasing the input to the CO of PLL 14 and advancing its phase. Alternatively, if the PLL 14 leads in phase, the PD Diff 18 outputs a negative error signal, which advances the phase of PLL 12 and retards the phase of PLL 14. Of course, the opposite convention could be implemented, in which the error signal is negative if PLL 12 leads PLL 14, and positive in the opposite case, with appropriate reversal of the addition and subtraction inputs at the adders 26, 28.

PD Diff 20 operates similarly, to eliminate any detected phase difference between PLL 14 and PLL 16. Note that the adder 28 of PLL 14 adds the error signal from PD Diff 18 to the output of its reference tracking feedback loop, and it subtracts the error signal from PD Diff 20 from the output of its reference tracking feedback loop.

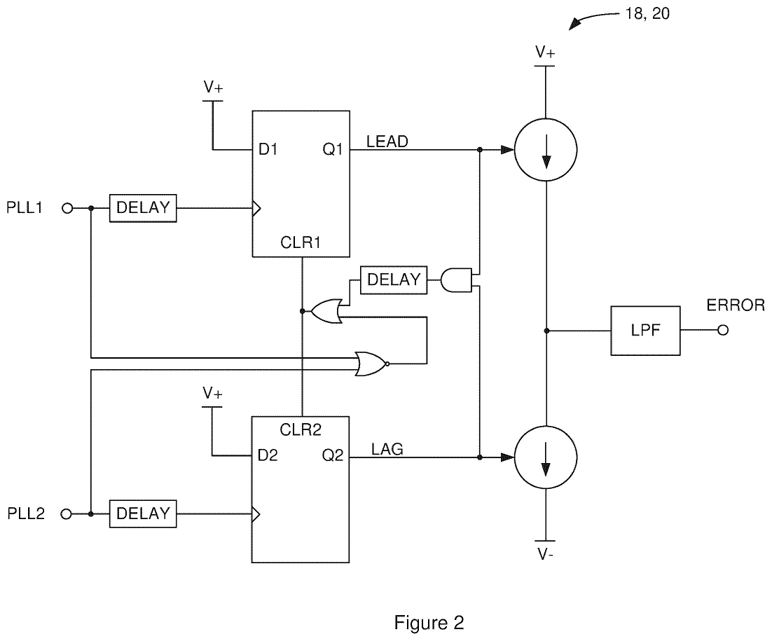

FIG. 2 depicts one representative implementation of the PD Diff 18, 20. The PD Diff 18, 20 operates similarly to a conventional PFD and CP. However, the flip flops are also reset by both input periodic signals being low. This eliminates the memory effect of a conventional PFD, and results in a phase detector looking only at edge timing, that does not detect differences in frequency. A low pass filter on the output smooths out the leading and lagging pulses, output by the flip flops, from the error signal.

In general, the PLLs 12, 14, 16 are each configured to control their COs in response to both the output of one or two PD Diffs 18, 20 to which they are connected, and the outputs of their own reference tracking feedback loops. FIG. 1 depicts one aspect, using adders 26, 28, 30 having both addition and subtraction inputs.

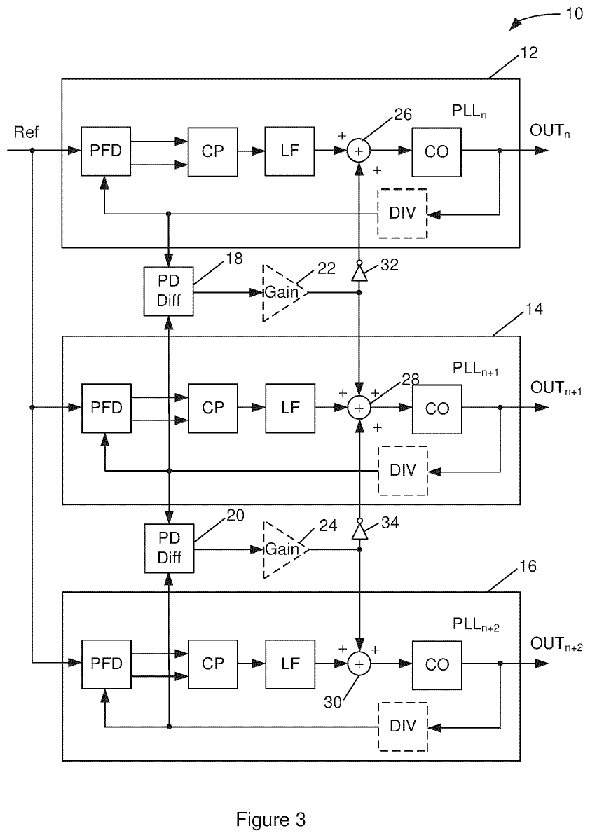

FIG. 3 depicts another aspect, in which each adder 26, 28, 30 adds together all its input signals, and inverters 32, 34 invert one leg of the error signal output by each PD Diff 18, 20. The inverters 32, 34 may each comprise, for example, an amplifier with a voltage gain of negative one.

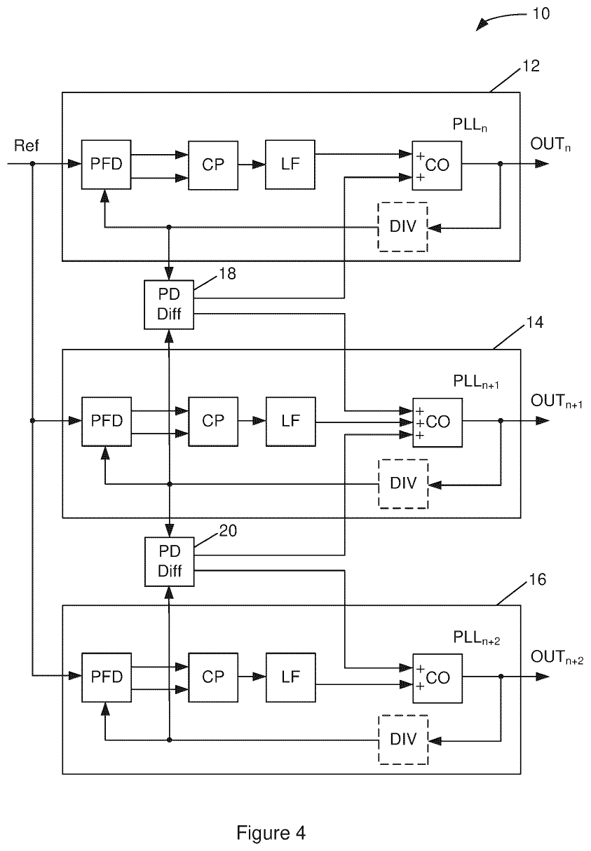

FIG. 4 depicts yet another aspect, in which each PD Diff 18, 20 outputs two error signals—e.g., a positive voltage to the connected PLL lagging in phase and a negative voltage to the connected PLL leading in phase. Alternatively, the PD Diffs 18, 20 could output error signals of the opposite polarity, with subtracting inputs at each CO. Note that the CO of the PLL 14, connected to two PD Diffs 18, 20, has three control inputs. In some aspects, buffers or amplifiers may be inserted into the error signal lines.

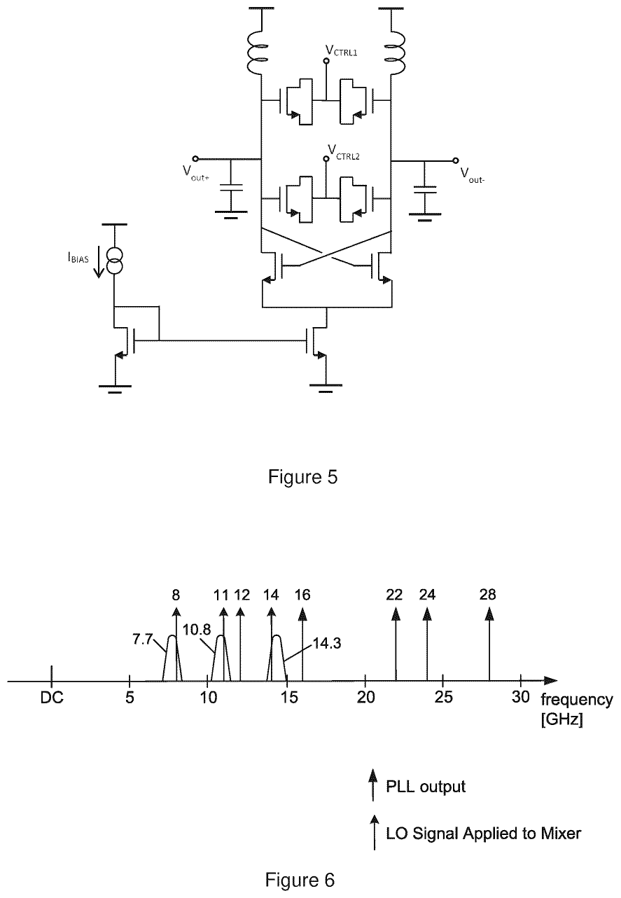

FIG. 5 is a schematic diagram of a CO having two control inputs V_{CTRL1} and V_{CTRL2}. The addition of further control inputs is straightforward. An input could be made subtracting by use of PMOS transistors as a variable capacitor, rather than NMOS as depicted.

Those of skill in the art will readily appreciate from these few examples that the PD Diff circuits 18, 20, and their interactions with the two PLLs connected to each, may be implemented in a broad variety of ways, to achieve the result of feeding back a phase difference error signal, forming a pairwise difference feedback loop in each of the attached PLLs, which is operative to minimize phase error between the PLLs.

At offset frequencies where the difference mode loop gain is high, the COs of the PLLs 12, 14, 16 will behave as a single oscillator, with improved phase noise, locked to the reference periodic signal by the reference tracking feedback loop. The level of phase noise improvement is 10·log(N) dB compared to a single oscillator, where N is the number of participating oscillators.

As mentioned above, PD Diffs 18, 20 may be implemented in a variety of ways, including, e.g., tri-state, sample-and-hold, or even mixer-based circuit topologies may be used. In some aspects, the PD Diffs 18, 20 may convert the phase error to a digital representation. The phase detection may be made synchronous to the output signals, and not necessarily to the reference clock in the case of a fractional-N PLL where the feed-back divider output period varies, which would otherwise largely restrict phase detector implementation.

In aspects where different or adjustable phase relations are required or desired between the PLL 12, 14, 16 outputs, phase adjustments can be made in any way known in the art-such as by adding an offset to the output of a PFD in a PLL 12, 14, 16. Since the pairwise difference feedback loop is only a proportional correction, the average phase relationship is not affected, but phase noise improvement and interaction mitigation between COs may be achieved regardless. In case a phase offset is imposed in the reference tracking feedback loop of a PLL 12, 14, 16, the PD Diff 18, 20 may receive a compensated input signal with less phase difference, or subtract an offset from its error signal, if necessary to avoid saturation due to large signals.

In some aspects, the dividers (DIV) in the PLLs 12, 14, 16 are integer dividers, wherein the divider may differ between PLLs 12, 14, 16. In this case, the PLLs 12, 14, 16 output periodic signals OUT (e.g., LO signals) at frequencies on a frequency grid, having a spacing of the reference periodic signal (Ref) frequency.

FIG. 6 is a frequency graph depicting an example of such an aspect. In this example, the reference frequency is 2 GHZ, and four PLL circuits have division numbers 8, 11, 12, and 14. These PLL circuits generate output signals at 16, 22, 24, and 28 GHz. These are divided by two, yielding the desired LO frequencies of 8, 11, 12, and 14 GHz. These fit well to carriers centered at 7.7, 10.8, and 14.3 GHZ.

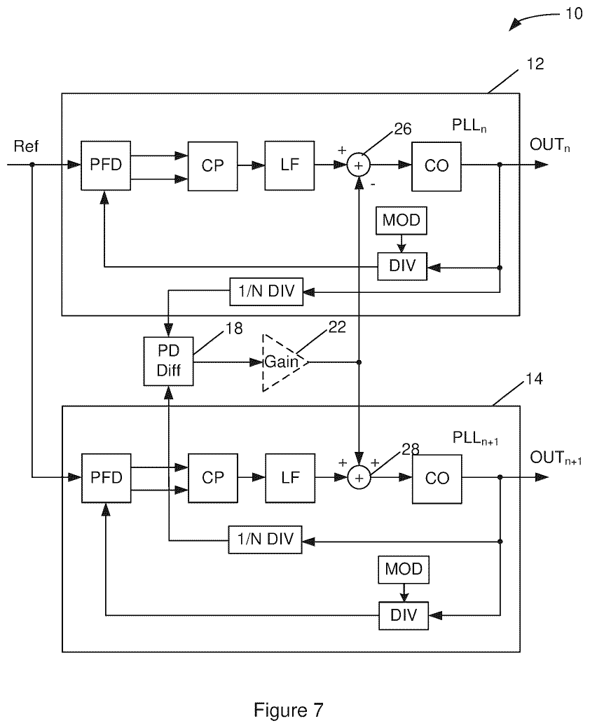

The integer dividers of the PLLs referenced in FIG. 6 are not a limitation. FIG. 7 depicts two PLLs 12, 14 in pairwise phase difference regulation, wherein the PLLs 12, 14 employ fractional-N frequency dividers in their reference tracking loop. As known in the art, fractional-N frequency division may, for example, be implemented with delta-sigma modulation, although other modulation techniques are also possible. In some aspects, the PLLs 12, 14 may each have a different fractional-N relationship to the reference frequency, so long as the relationship between their output frequencies is an integer number, as described above. In this aspect, the PLLs 12, 14 each additionally include an integer frequency divider for the pairwise difference feedback loop. In this case, the frequency of the signals used for the pairwise difference feedback loop will deviate slightly from the reference frequency.

In some aspects, the periodic signals for the pairwise difference loop are obtained by dividing the output periodic signal of the respective PLL by different numbers. In one aspects, the numbers have an integer ratio no larger than 10. In another aspect, the numbers have a rational ratio, with the numerator and denominator being integers no larger than 10.

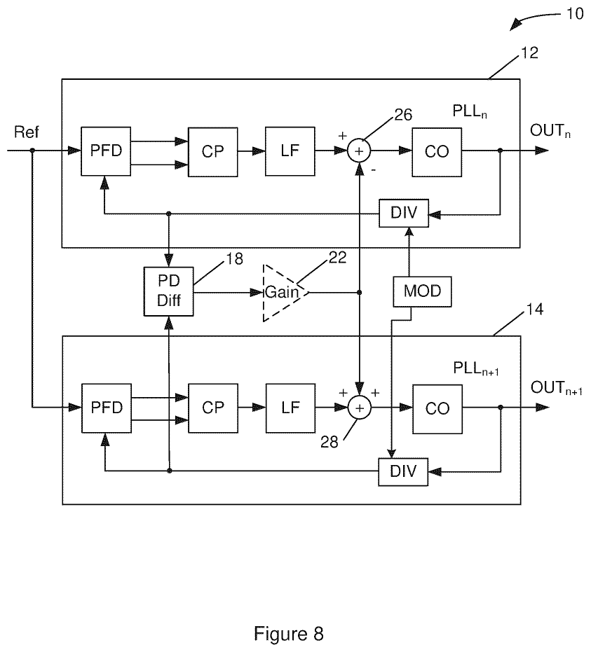

FIG. 8 depicts an aspect in which both PLLs 12, 14 employ the same fractional-N divider for both the reference tracking loop and the pairwise difference feedback loop. In this case, a common modulator controls the fractional-N dividers of both (all) PLLs 12, 14 in the pairwise difference feedback loop.

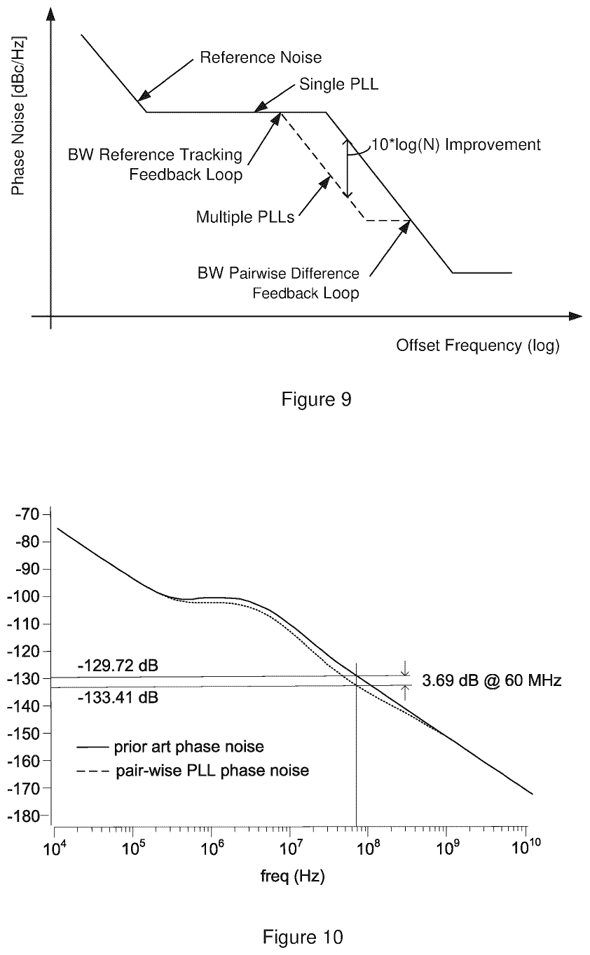

FIG. 9 plots the phase noise at the output of a single PLL, as well as the phase noise of an output of the PLL system 10 of FIG. 1. As FIG. 9 shows, the multiple PLL system 10 with pairwise phase difference regulation improves phase noise in both the in-band region and in the region dominated by oscillator noise. When the pairwise difference feedback loop gain is high, the improvement in the oscillator-dominated phase noise region will be close to 10·log(N) dB since the different oscillators will then be locked together to effectively behave as a single oscillator, with N times the signal energy. In the in-band region, the improvement is largest in the higher frequency part, where the reference tracking loop bandwidth reduction has the greatest effect.

The theoretical maximum phase noise improvement for the system 10 of FIG. 1, comprising three oscillators, is 10 log(3)=4.77 dB. The PLL system 10 of FIG. 1 was simulated, as well as a comparable system comprising three conventional PLLs without the pairwise phase difference regulation. FIG. 10 plots the phase noise for both simulations, showing a phase noise improvement of the PLL system 10 of about 3.7 dB. This improvement is limited by reference phase noise contribution, and by limited pairwise difference feedback loop gain.

The pairwise difference feedback loops are essentially additional type-I PLLs (on top of the reference tracking type-II loops). These contain one integrator in the controlled oscillator CO, meaning that the bandwidth, at up to which the correction is effective, is proportional to the low frequency total loop gain. The bandwidth that could be achieved with robust loop stability depends on the comparison frequency used, where common practice for PLL bandwidth is not to exceed about 1/10 of the comparison frequency.

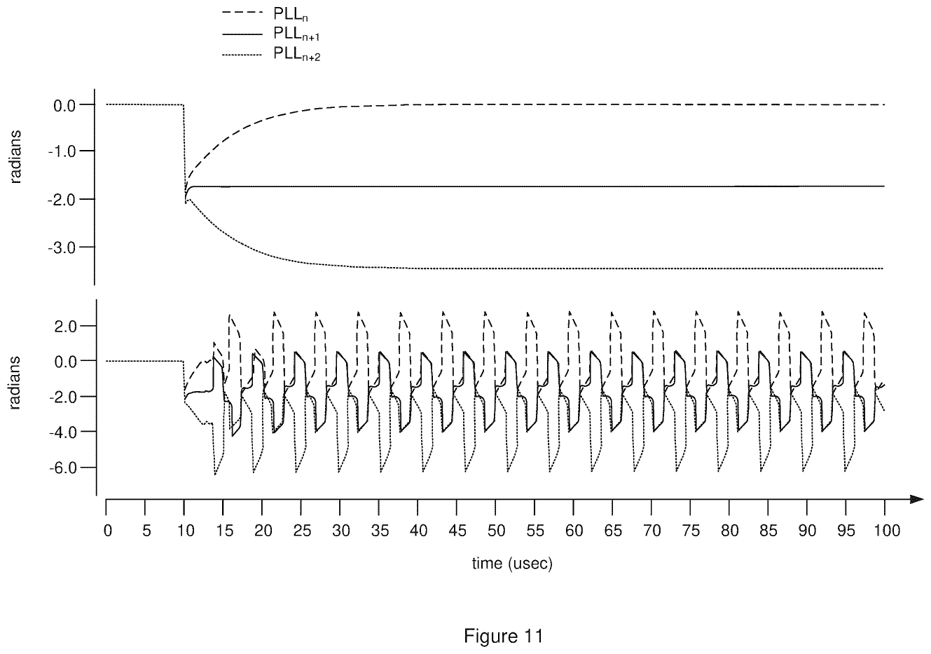

FIG. 11 plots the results of phase steps applied to two of the PLLs of each simulated system—with equal target phase difference between adjacent PLLs. This demonstrates the stability of the systems. In a first simulation, a 100-degree (1.744 radians) target phase shift was applied. PLL CO control signal responses are shown. Oscillators are of an LC-type and mutually coupled through the inductances. The response of the PLL system 10 having pairwise phase difference regulation is plotted on the top; the response of the prior art three-PLL system without such phase difference regulation is plotted on the bottom. These graphs show the vastly improved stability of the system 10 of FIG. 1.

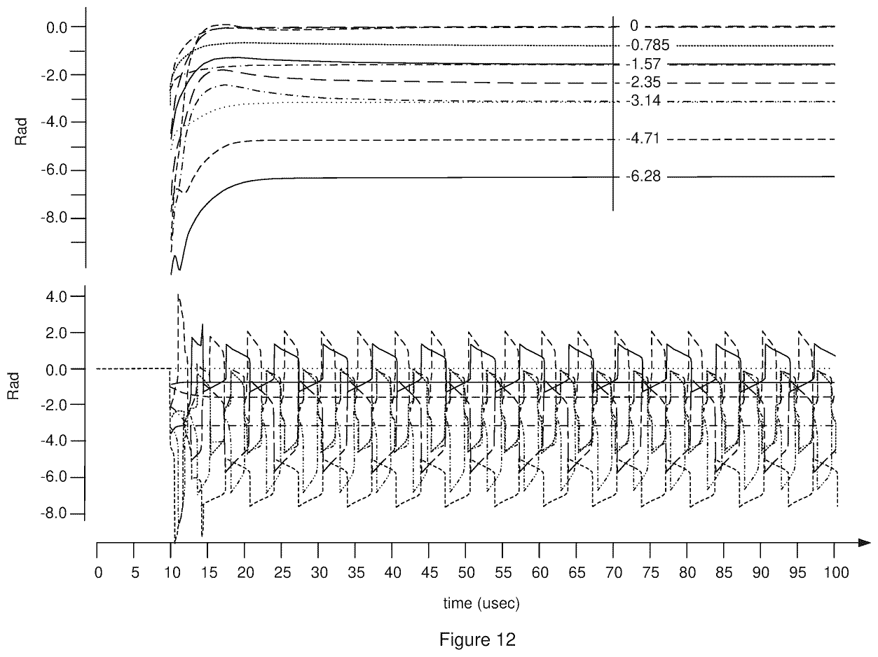

FIG. 12 plots the PLL CO control signal responses, on both simulated systems, as targeted phase shifts were swept between 0 and 180 degrees, in steps of 45 degrees. The curves show the phase of PLL output signals in radians. The following table lists the responses for each PLL, for each targeted phase shift.

| | phase (rad) | phase (deg) |
|---|---|---|
| PLL0 | 0.0 | 0.0 |
| | −2.39009 | 45.0 |
| | −2.53925 | 90.0 |
| | −1.3137 | 135.0 |
| | −966.625 | 180.0 |
| PLL1 | 0.0 | 0.0 |
| | −780.799 | 45.0 |
| | −1.56549 | 90.0 |
| | −2.35261 | 135.0 |
| | −3.1382 | 180.0 |
| PLL2 | 0.0 | 0.0 |
| | −1.57126 | 45.0 |
| | −3.14145 | 90.0 |
| | −4.71095 | 135.0 |
| | −6.28081 | 180.0 |

In the prior art PLLs, with results plotted at the bottom, not all phase differences result in oscillation, but most do. In contrast, the PLL system 10 of FIG. 1, with results plotted on the top, was able to avoid oscillation in all cases, and each PLL settled at its targeted phase. Note that many of the 15 plots (e.g., most for PLL0, which differ by milliradians or less) are overlaid on the graph.

These simulations demonstrate that the pairwise phase difference regulation of aspects of the present disclosure provide improved stability of a distributed PLL system, without sacrificing noise performance-which would be the result of simply increasing the PLL bandwidth of a conventional system.

The pairwise phase difference regulation may be implemented in a variety of ways. FIGS. 1, 3, and 4 demonstrate one, in which adjacent PLLs 12, 14, 16 arranged in a row are connected to PD Diff circuits 18, 20 between the PLLs 12, 14, 16. In this system 10, the outer edge PLLs 12, 16 connect to one PD Diff 18, 20 each, and all inner PLLs 14 connect to two PD Diffs 18, 20.

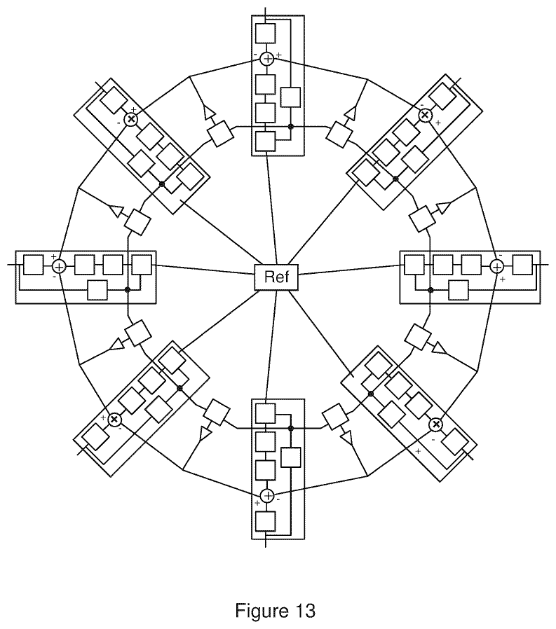

FIG. 13 demonstrates another topology, in which PLLs are arranged in a ring, and each PLL connects, via two PD Diff circuits, to two neighbor PLLs.

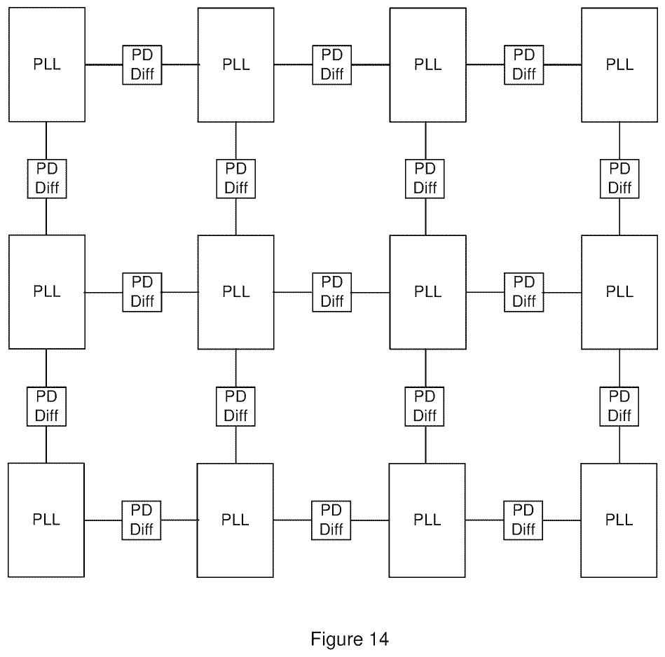

FIG. 14 depicts another topology, in which PLLs are arranged in a grid. In this connection scheme, each inner PLL connects to four neighbors; each edge PLL connects to three neighbors; and each corner PLL connects to two neighbors. The phase difference regulation is still “pairwise,” in that each PD Diff circuit compares the phases of two PLLs; however, the PLLs participate in multiple such pairwise phase regulations. In aspects where PLLs connect to different numbers of other PLLs, different weights are applied to the phase difference error signals, so that the outputs of, e.g., the adders 26, 28, 30 (FIG. 1) are the same in response to an equal amount of phase disturbance of the corresponding PLL output signal, to maintain the bandwidth of the phase difference regulation loop response. Weighting of the phase difference error signals for other implementations (e.g., the aspects shown in FIGS. 3 and 4) is straightforward for those of skill in the art.

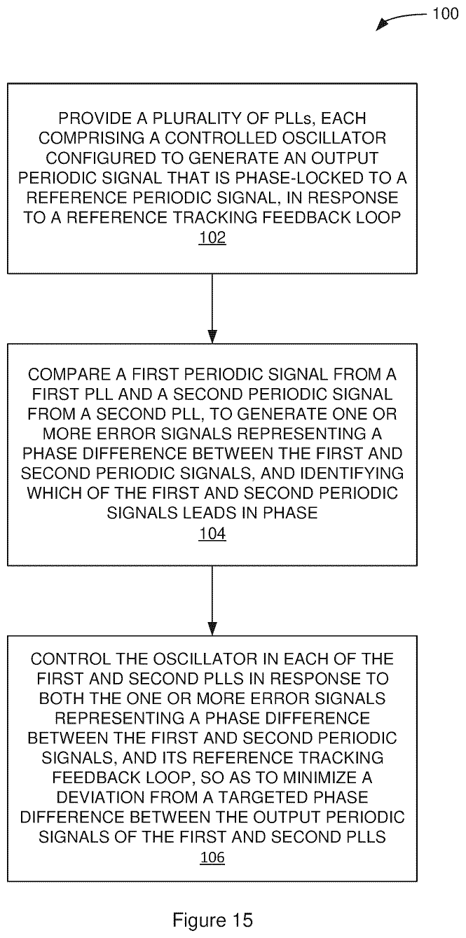

FIG. 15 depicts steps in a method 100 of generating a plurality of periodic signals. A plurality of PLLs 12, 14, 16 is provided. Each PLL 12, 14, 16 comprises a controlled oscillator CO configured to generate an output periodic signal OUT that is phase-locked to a reference periodic signal Ref, in response to a reference tracking feedback loop (block 102). A first periodic signal from a first PLL 12 is compared to a second periodic signal from a second PLL 14, to generate one or more error signals representing a phase difference between the first and second periodic signals, and identifying which of the first and second periodic signals leads in phase (block 104). The oscillator in each of the first and second PLLs 12, 14 is controlled in response to both the one or more error signals representing a deviation from a targeted phase difference between the first and second periodic signals, and its reference tracking feedback loop, so as to minimize a phase difference between the output periodic signals OUT of the first and second PLLs 12, 14 (block 106).

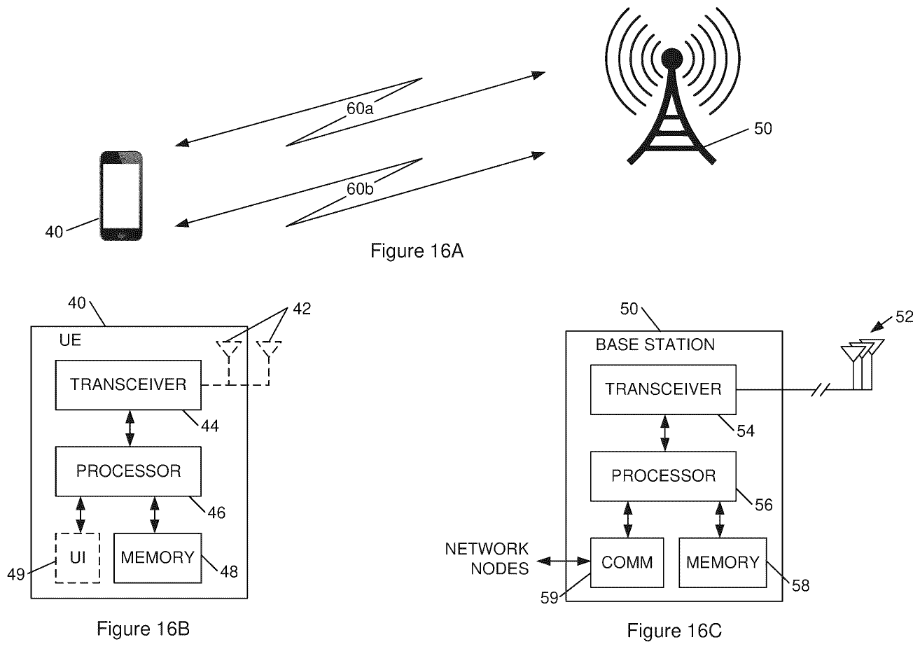

FIG. 16A is a diagram of wireless transmission over the air interface of a wireless communication network. A User Equipment (UE) 40, such as a smartphone, receives and transmits modulated Radio Frequency (RF) signals, e.g., over multiple antennas, from and to a base station 50, such as an LTE eNB or an NR gNB. In one aspect the wireless transmission employs Multiple Input, Multiple Output (MIMO) technology, wherein RF signals 60a, 60b employ spatial diversity and/or spatial multiplexing to increase robustness against fading or co-channel interference, and to improve bitrates, by transmitting on separate paths between respective multiple antennas at the UE 40 and base station 50. Although only two RF signals 60a, 60b are shown, in general MIMO transmissions may comprise multiple separate transmissions (e.g., 2, 4, 8, . . . , 128, or more). At each of the UE 40 and base station 50, multiple transceivers, associated with the multiple antennas, receive and transmit RF signals. These transceivers require multiple phase-locked Local Oscillator (LO) signals for accurate frequency conversion. Additionally or alternatively, one or both of the UE 40 and base station 50 may implement beamforming, wherein the directionality of an antenna is increased and controlled by controlling the phases of the signals to/from multiple antenna elements when transmitting or receiving by a phased array antenna. In this application also, multiple transceivers each require a phase-locked LO signal.

FIG. 16B is a block diagram of the UE 40 of FIG. 16X. As used herein, the term UE may refer to a user-operated telephony terminal, a machine-to-machine (M2M) device, a machine-type communications (MTC) device, a Narrowband Internet of Things (NB-IoT) device (in particular a UE implementing the 3GPP standard for NB-IoT), etc. A UE 40 may also be referred to as a radio device, a radio communication device, a wireless communication device, a wireless terminal, or simply a terminal-unless the context indicates otherwise, the use of any of these terms is intended to include device-to-device UEs or devices, machine-type devices or devices capable of machine-to-machine communication, sensors equipped with a radio network device, wireless-enabled table computers, mobile terminals, smartphones, laptop-embedded equipped (LEE), laptop-mounted equipment (LME), USB dongles, wireless customer-premises equipment (CPE), and the like.

The UE 40 transmits and receives RF signals (including MIMO signals) on at least one antenna 42, which may be internal or external, as indicated by dashed lines. The RF signals are generated, and received, by one or more transceiver circuits 44. The transceiver circuits 44, as well as other components of the UE 40, are controlled by processing circuitry 46. Memory 48 operatively connected to the processing circuitry 46 stores software in the form of computer instructions operative to control the processing circuitry 46. A user interface 49 may include output devices such as a display and speakers (and/or a wired or wireless connection to audio devices such as ear buds), and/or input devices such as buttons, a keypad, a touchscreen, and the like. As indicated by the dashed lines, the user interface 49 may not be present in all UEs 40; for example, UEs 40 designed for Machine Type Communications (MTC) such as Internet of Things (IoT) devices, may perform dedicated functions such as sensing/measuring, monitoring, meter reading, and the like, and may not have any user interface 49 features.

FIG. 16C is a block diagram of the base station 50 of FIG. 16A. A base station 50—known in various network implementations as a Radio Base Station (RBS), Base Transceiver Station (BTS), Node B (NB), enhanced Node B (eNB), Next Generation Node B (gNB), or the like—is a node of a wireless communication network that implements a Radio Access Network (RAN) in a defined geographic area called a cell, by providing radio transceivers to communicate wirelessly with a plurality of UEs 40.

The base station 50 transmits and receives RF signals (including MIMO signals) on a plurality of antennas 52. As indicated by the broken line, the antennas 52 may be located remotely from the base station 50, such as on a tower or building. The RF signals are generated, and received, by one or more transceiver circuits 54. The transceiver circuits 54, as well as other components of the base station 50, are controlled by processing circuitry 56. Memory 58 operatively connected to the processing circuitry 56 stores instructions operative to control the processing circuitry 56. Although the memory 58 is depicted as being separate from the processing circuitry 56, those of skill in the art understand that the processing circuitry 56 includes internal memory, such as a cache memory or register file. Those of skill in the art additionally understand that virtualization techniques allow some functions nominally executed by the processing circuitry 56 to actually be executed by other hardware, perhaps remotely located (e.g., in the so-called “cloud”). Communication circuitry 59 provides one or more communication links to one or more other network nodes, propagating communications to and from UEs 40, from and to other network nodes or other networks, such as telephony networks or the Internet.

In all embodiments, the processing circuitry 46, 56 may comprise any sequential state machine operative to execute machine instructions stored as machine-readable computer programs in memory 48, 58, such as one or more hardware-implemented state machines (e.g., in discrete logic, FPGA, ASIC, etc.); programmable logic together with appropriate firmware; one or more stored-program, general-purpose processors, such as a microprocessor or Digital Signal Processor (DSP), together with appropriate software; or any combination of the above.

In all embodiments, the memory 48, 58 may comprise any non-transitory machine-readable media known in the art or that may be developed, including but not limited to magnetic media (e.g., floppy disc, hard disc drive, etc.), optical media (e.g., CD-ROM, DVD-ROM, etc.), solid state media (e.g., SRAM, DRAM, DDRAM, ROM, PROM, EPROM, Flash memory, solid state disc, etc.), or the like.

In all embodiments, the transceiver circuits 44, 54 are operative to communicate with one or more other transceivers via a Radio Access Network (RAN) according to one or more communication protocols known in the art or that may be developed, such as IEEE 802.xx, CDMA, WCDMA, GSM, LTE, UTRAN, WiMax, NB-IoT, or the like. The transceiver 44, 54 implements transmitter and receiver functionality appropriate to the RAN links (e.g., frequency allocations and the like). The transmitter and receiver functions may share circuit components and/or software, or alternatively may be implemented separately. In particular, the transceiver circuits 44, 54 employ a distributed LO signal generation scheme, in which a plurality of PLLs each generate LO signals as required for frequency conversion and the like. Alternatively, the transceiver circuits 44, 54 may employ direct RF conversion. To mitigate the deleterious effects of coupling of oscillators in the various PLLs, according to aspects of the present disclosure, pairwise phase difference regulation is performed on associated pairs of PLLs, as described herein.

In all embodiments, the communication circuitry 59 may comprise a receiver and transmitter interface used to communicate with one or more other nodes over a communication network according to one or more communication protocols known in the art or that may be developed, such as Ethernet, TCP/IP, SONET, ATM, IMS, SIP, or the like. The communication circuits 59 implement receiver and transmitter functionality appropriate to the communication network links (e.g., optical, electrical, and the like). The transmitter and receiver functions may share circuit components and/or software, or alternatively may be implemented separately.

Aspects of the present disclosure thus provide for distributed PLLs, which supports modularity of design and power savings by avoiding the distribution of high frequency signals. The pairwise phase difference regulation disclosed herein locks the PLLs to each other with high bandwidth, thus reducing phase noise and effects of potential undesired oscillator coupling. However, the bandwidth of the PLLs' reference tracking loops is set independently of the pairwise phase difference regulation bandwidth, to optimize phase noise performance. The pairwise phase difference regulation disclosed herein is localized, avoiding, e.g., the distribution of multiple phase difference error signals to a central processor, and correction signals back to each PLL. Minimal additional hardware with only incremental complexity is required to achieve significant performance improvements. Compared to prior art distributed PLL systems, the pairwise phase difference regulation according to aspects of the present disclosure reduces the effects of oscillator interaction; reduces both in-band and out-of-band phase noise; preserves design modularity by requiring only limited additional high frequency signal distribution; enables short design times by relaxing component matching requirements; and can be easily implemented as an addition to existing designs.

Any appropriate steps, methods, features, functions, or benefits disclosed herein may be performed through one or more functional units or modules of one or more virtual apparatuses. Each virtual apparatus may comprise a number of these functional units. These functional units may be implemented via processing circuitry, which may include one or more microprocessor or microcontrollers, as well as other digital hardware, which may include digital signal processors (DSPs), special-purpose digital logic, and the like. The processing circuitry may be configured to execute program code stored in memory, which may include one or several types of memory such as read-only memory (ROM), random-access memory (RAM), cache memory, flash memory devices, optical storage devices, etc. Program code stored in memory includes program instructions for executing one or more telecommunications and/or data communications protocols as well as instructions for carrying out one or more of the techniques described herein. In some implementations, the processing circuitry may be used to cause the respective functional unit to perform corresponding functions according one or more embodiments of the present disclosure.

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the aspects disclosed herein may be applied to any other aspect, wherever appropriate. Likewise, any advantage of any of the aspects may apply to any other aspect, and vice versa. Other objectives, features, and advantages of the enclosed aspects will be apparent from the description.

The term unit may have conventional meaning in the field of electronics, electrical devices and/or electronic devices and may include, for example, electrical and/or electronic circuitry, devices, modules, processors, memories, logic solid state and/or discrete devices, computer programs or instructions for carrying out respective tasks, procedures, computations, outputs, and/or displaying functions, and so on, as such as those that are described herein. As used herein, the term “configured to” means set up, organized, adapted, or arranged to operate in a particular way; the term is synonymous with “designed to.” As used herein, the term “substantially” means nearly or essentially, but not necessarily completely; the term encompasses and accounts for mechanical or component value tolerances, measurement error, random variation, and similar sources of imprecision. As used herein, the term RF stands for Radio Frequency, and includes frequencies in the range 20 kHz to 300 GHz. Accordingly, “RF” includes microwave and millimeter wave frequencies.

Some of the aspects contemplated herein are described more fully with reference to the accompanying drawings. Other aspects, however, are contained within the scope of the subject matter disclosed herein. The disclosed subject matter should not be construed as limited to only the aspects set forth herein; rather, these aspects are provided by way of example to convey the scope of the subject matter to those skilled in the art.

1-29. (canceled)

30. A pairwise phase difference regulation system comprising:
first and second Phase Locked Loops (PLL) each comprising a controlled oscillator configured to generate an output periodic signal that is phase-locked to a reference periodic signal, in response to a reference tracking feedback loop;
a first phase difference detector configured to receive a first periodic signal from the first PLL and a second periodic signal from the second PLL, and output one or more error signals representing a deviation from a targeted phase difference between the first and second periodic signals, and identifying which of the first and second periodic signals leads in phase;
wherein each of the first and second PLLs is configured to control its oscillator in response to both the one or more error signals representing a phase difference between the first and second periodic signals and its reference tracking feedback loop;
whereby the first phase difference detector and first and second PLLs form a pairwise phase difference feedback loop operative to minimize a deviation from a targeted phase difference between the output periodic signals of the first and second PLLs.

31. The pairwise phase difference regulation system of claim 30, wherein the first and second periodic signals are the output periodic signals of the first and second PLLs.

32. The pairwise phase difference regulation system of claim 30, wherein the first and second periodic signals are divided output periodic signals of the first and second PLLs.

33. The pairwise phase difference regulation system of claim 32, wherein the first and second periodic signals are obtained by dividing the output periodic signal of the respective PLL by different numbers, the numbers having an integer ratio no larger than 10, or a rational ratio with the numerator and denominator being integers no larger than 10.

34. The pairwise phase difference regulation system of claim 30, wherein, for each of the first and second PLLs, the pairwise difference feedback loop has a higher bandwidth than the reference tracking feedback loop.

35. The pairwise phase difference regulation system of claim 34 wherein the higher bandwidth of the pairwise difference feedback loop mitigates effects of a coupling of oscillators in the first and second PLLs.

36. The pairwise phase difference regulation system of claim 30, further characterized by a gain circuit interposed in a path of the one or more error signals output by the first phase difference detector.

37. The pairwise phase difference regulation system of claim 30, wherein
the one or more error signals comprise one error signal, wherein a magnitude of the error signal indicates the phase difference of the first and second periodic signals, and a polarity of the error signal indicates which of the first and second periodic signals leads in phase.

38. The pairwise phase difference regulation system of claim 37, wherein
the first PLL subtracts the one error signal from an output of its reference tracking feedback loop to generate an oscillator control signal; and
the second PLL adds the one error signal to an output of its reference tracking feedback loop to generate an oscillator control signal.

39. The pairwise phase difference regulation system of claim 38, wherein the error signal is connected to one PLL directly and is connected to the other PLL through an inverting amplifier, and wherein both the first and second PLLs add the error signal to an output of its reference tracking feedback loop to generate an oscillator control signal.

40. The pairwise phase difference regulation system of claim 30, wherein
the one or more error signals comprise first and second error signals, each having the same magnitude indicative of the detected deviation but different polarities, and each routed to a different one of the first and second PLLs; and
the error signal polarity indicates whether the respective first or second periodic signal leads in phase.

41. The pairwise phase difference regulation system of claim 40, wherein, in each of the first and second PLLs, an output of the reference tracking feedback loop is connected to a first frequency control input of the controlled oscillator (CO), and each received error signal from a phase difference detector is connected to a second frequency control input of the controlled oscillator (CO).

42. The pairwise phase difference regulation system of claim 30, further comprising:
a third PLL comprising a controlled oscillator configured to generate an output periodic signal that is phase-locked to the reference periodic signal, in response to a reference tracking feedback loop;
a second phase difference detector configured to receive the second periodic signal and a third periodic signal from the third PLL, and output one or more error signals representing a deviation from a targeted phase difference between the second and third periodic signals, and identifying which of the second and third periodic signals leads in phase;
wherein the second PLL is further configured to control its oscillator also in response to the one or more error signals representing a phase difference between the second and third periodic signals; and
wherein the third PLL is configured to control its oscillator in response to both the one or more error signals representing a phase difference between the second and third periodic signals and its reference tracking feedback loop;
whereby the second phase difference detector and second and third PLLs form a pairwise difference feedback loop operative to minimize a deviation from a targeted phase error between the output periodic signals of the second and third PLLs.

43. The pairwise phase difference regulation system of claim 30, wherein the targeted phase error between the output periodic signals of two PLLs in a pairwise difference feedback loop is zero.

44. The pairwise phase difference regulation system of claim 30, wherein weights are applied to the phase difference error signals in response to the number of pairwise difference feedback loops in which a PLL participates.

45. The pairwise phase difference regulation system of claim 32, wherein each PLL includes a fractional-N frequency divider in its reference tracking feedback loop, and an integer frequency divider to generate the periodic signal in the pairwise phase difference feedback loop.

46. The pairwise phase difference regulation system of claim 3, wherein each PLL includes a fractional-N frequency divider in both its reference tracking feedback loop and pairwise phase difference feedback loop, and further comprising a fractional-N modulator circuit configured to control the fractional-N frequency divider of each PLL in a pairwise phase difference feedback loop.

47. A method of generating a plurality of periodic signals, comprising:
providing a plurality of Phase Locked Loops (PLL) each comprising a controlled oscillator configured to generate an output periodic signal that is phase-locked to a reference periodic signal, in response to a reference tracking feedback loop
comparing a first periodic signal from a first PLL and a second periodic signal from a second PLL, to generate one or more error signals representing a phase difference between the first and second periodic signals, and identifying which of the first and second periodic signals leads in phase;
controlling the oscillator in each of the first and second PLLs in response to both the one or more error signals representing a phase difference between the first and second periodic signals, and its reference tracking feedback loop, so as to minimize a deviation from a targeted phase difference between the output periodic signals of the first and second PLLs.

48. User Equipment (UE) operative in a wireless communication network, the UE including one or more transceiver circuits comprising:
first and second Phase Locked Loops, PLL, each comprising a controlled oscillator configured to generate an output periodic signal that is phase-locked to a reference periodic signal, in response to a reference tracking feedback loop;
a first phase difference detector configured to receive a first periodic signal from the first PLL and a second periodic signal from the second PLL, and output one or more error signals representing a deviation from a targeted phase difference between the first and second periodic signals, and identifying which of the first and second periodic signals leads in phase;
wherein each of the first and second PLLs is configured to control its oscillator in response to both the one or more error signals representing a phase difference between the first and second periodic signals and its reference tracking feedback loop;
whereby the first phase difference detector and first and second PLLs form a pairwise phase difference feedback loop operative to minimize a deviation from a targeted phase difference between the output periodic signals (OUT) of the first and second PLLs.

49. A base station, operative in a wireless communication network, the base station including one or more transceiver circuits comprising:
first and second Phase Locked Loops (PLL) each comprising a controlled oscillator configured to generate an output periodic signal that is phase-locked to a reference periodic signal, in response to a reference tracking feedback loop;
a first phase difference detector configured to receive a first periodic signal from the first PLL and a second periodic signal from the second PLL, and output one or more error signals representing a deviation from a targeted phase difference between the first and second periodic signals, and identifying which of the first and second periodic signals leads in phase;
wherein each of the first and second PLLs is configured to control its oscillator in response to both the one or more error signals representing a phase difference between the first and second periodic signals and its reference tracking feedback loop;
whereby the first phase difference detector and first and second PLLs form a pairwise phase difference feedback loop operative to minimize a deviation from a targeted phase difference between the output periodic signals of the first and second PLLs.
